(19) United States
(12) Patent Application Publication
(10) Pub. No.: US 2021/0191461 A1
(43) Pub. Date: Jun. 24, 2021

(54) EXTERNAL COOLING MODULE

(71) Applicant: Advanced Micro Devices, Inc., Santa Clara, CA (US)

(72) Inventors: Christopher Jaggers, Austin, TX (US); Constantine Conrad Peter Venizelos, Alpharetta, GA (US)

(73) Assignee: Advanced Micro Devices, Inc., Santa Clara, CA (US)

(21) Appl. No.: 16/725,123

(22) Filed: Dec. 23, 2019

(51) Int. Cl. G06F 1/16; H05K 7/20; G06F 1/20

(52) U.S. Cl. CPC G06F 1/1632; H05K 7/20145; H05K 7/20209; G06F 1/206; G06F 1/203; H05K 7/20172

(57) ABSTRACT

An external module is for use with a designated computing device. The external module includes a body forming a hollow chamber. An external air intake formed in the body and connected to a first portal of the chamber. An air outlet formed in the body along a wall of the chamber and adapted to align with a cooling air intake of the designated computing device when the external module is positioned in a designated relationship to the computing device. A blower is positioned to force air through the external air intake into the chamber and maintain a positive air pressure in the chamber such that the positive air pressure is maintained against at least part of the cooling air intake of the computing device when the air outlet is aligned with the cooling air intake.

### BACKGROUND

Computer systems typically include a cooling subsystem to dissipate heat produced by the computer's central processing unit (CPU), other integrated circuits and power supply circuitry. Cooling subsystems often include a thermal block mounted to the CPU, which is thermally connected to a heat sink or one or more heat pipes. If heat pipes are used, typically a heat spreader or heat sink is thermally connected to the opposite end of the heat pipe from the CPU. An internal fan is often used to direct air over the heat sink, increasing the amount of heat dissipated through convection.

In consumer computers, such cooling subsystems are often designed for a typical operating profile in which the CPU consumes a low or moderate amount of power most of the time, but occasionally is boosted to handle heavy processing loads during which it consumes more power and produces more heat. When used for processor-intensive applications such as gaming or video editing, such computers tend to generate excess heat, resulting in the processor being “throttled” or slowed down in order to consume less power and generate less heat. Some computers, such as tablet computers and some notebook type computers, are fanless and rely on radiation and ambient airflow to dissipate most of the heat. Since they have less cooling ability, the performance of the CPU in laptop, tablet, and notebook computers is frequently limited to an amount lower than its capability.

External cooling pads are sometimes used to help cool computers. Typically, cooling pads include one or more fans that direct air against the external surface or “skin” of the computer.

### BRIEF DESCRIPTION OF THE DRAWINGS

FIG. 1 is a top perspective view of an external cooling module according to some embodiments;

FIG. 2 is a bottom perspective view of the external cooling module of FIG. 1;

FIG. 3 is a cutaway top perspective view of the external cooling module of FIG. 1;

FIG. 4 is a bottom perspective view of a notebook computer with which the external cooling module of FIG. 1 is designated to operate;

FIG. 5 illustrates in mixed cross-section and block diagram form an external cooling module paired with a computer according to some embodiments;

FIG. 6 is a cross-section block diagram showing a portion of a hollow chamber aligned with a computer cooling air intake according to some embodiments;

FIG. 7 is a cross-section block diagram showing a portion of another hollow chamber aligned with a computer cooling air intake according to additional embodiments;

FIG. 8 is a cross section block diagram of an external cooling module paired with a computer according to some embodiments; and

FIG. 9 is a cross section block diagram of another external cooling module paired with a computer according to some embodiments.

In the following description, the use of the same reference numerals in different drawings indicates similar or identical items. Unless otherwise noted, the word “coupled” and its associated verb forms include both direct connection and indirect electrical connection by means known in the art, and unless otherwise noted any description of direct connection implies alternate embodiments using suitable forms of indirect electrical connection as well.

### DETAILED DESCRIPTION OF ILLUSTRATIVE EMBODIMENTS

An external module is for use with a designated computing device. The external module includes a body forming a hollow chamber. An external air intake formed in the body and connected to a first portal of the chamber. An air outlet formed in the body along a wall of the chamber and adapted to align with a cooling air intake of the designated computing device when the external module is positioned in a designated relationship to the computing device. A blower is positioned to force air through the external air intake into the chamber and maintain a positive air pressure in the chamber such that the positive air pressure is maintained against at least part of the cooling air intake of the computing device when the air outlet is aligned with the cooling air intake.

A method uses an external cooling module to increase airflow in a cooling system of a computing device. The method includes aligning an air outlet of a chamber of an external cooling module with a cooling air intake of a computing device. Air is driven from an air intake to the chamber to pressurize the chamber with a positive air pressure. The method includes maintaining a positive air pressure against at least part of the cooling air intake of the computing device to increase airflow through a cooling system of the computing device.

A system includes a portable computing device and an external module. The portable computing device including a cooling subsystem with a cooling air intake, a fan positioned to direct air toward selected components of the portable computing device, and an air outlet positioned to expel the air after it passes the selected components. The external module is adapted for pairing with the portable computing device, and includes a body, a chamber, an external air intake, an air outlet, and a blower. The body forms the chamber with the external air intake formed in the body and connected to a first portal of the chamber. The air outlet formed in the body along a wall of the chamber and adapted to align with a cooling air intake of the portable computing device when the external module is positioned in a designated relationship to the portable computing device. The blower is positioned to force air through the external air intake into the chamber and maintain a positive air pressure in the chamber such that a positive air pressure is maintained against at least part of the cooling air intake of the portable computing device when the air outlet is aligned with cooling air intake.

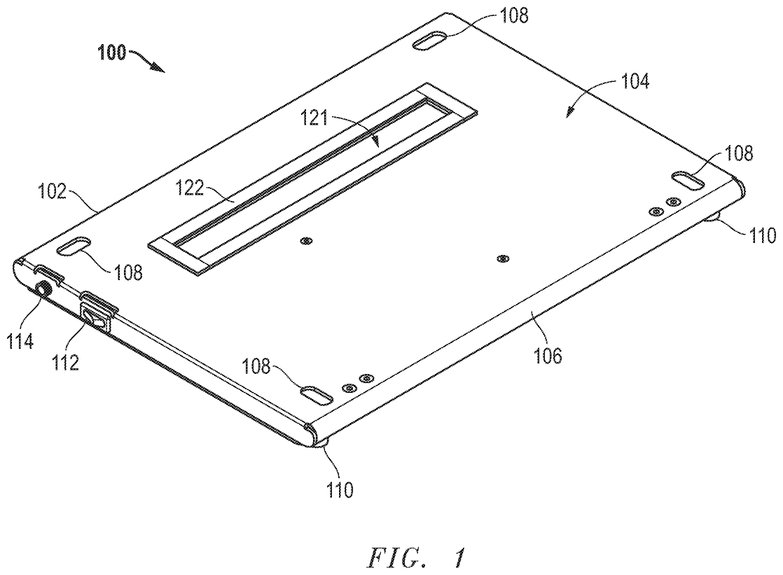

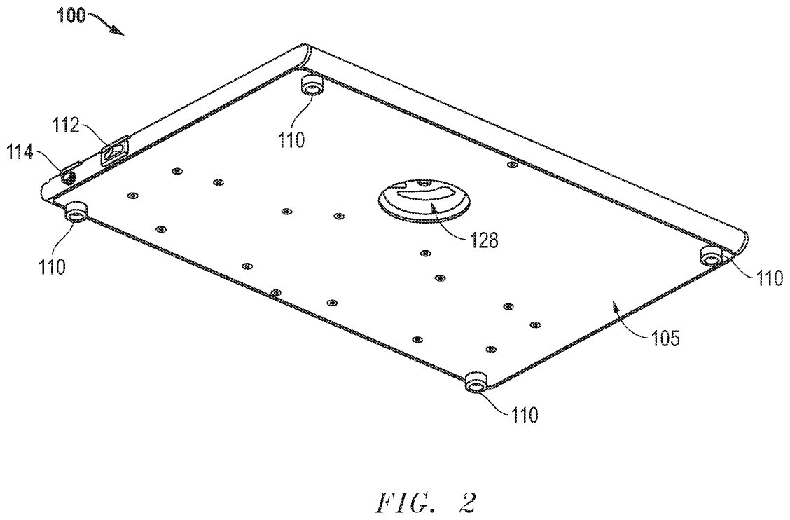

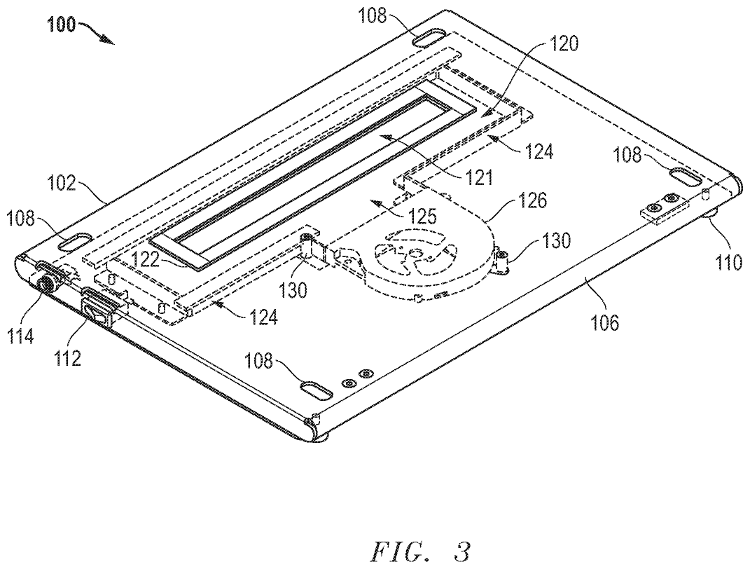

FIG. 1 is a top perspective view of a external cooling module 100 according to some embodiments. In this implementation, external cooling module 100 includes a body 102 having a top side 104 and a front side 106. Body 102 is sized to hold a particular designated notebook computer along top side 104. Indentations 108 are positioned to hold the feet of the designated notebook computer to stabilize the notebook computer when it is placed in a designated relationship atop external cooling module 100. Support feet 110 are presented along the bottom face of external cooling module 100, and are tall enough to allow airflow underneath external cooling module 100 when it is placed on a hard surface. The cooling elements of external cooling module 100 will be described further with respect to FIGS. 2-3.

FIG. 2 is a bottom perspective view of the external cooling module 100 of FIG. 1. FIG. 3 is a cutaway top perspective view of the external cooling module 100 of FIG. 1. Referring to FIGS. 1-3, generally the body 102 forms a hollow chamber 120 having an air outlet 121 presented along top side 104. Hollow chamber 120 is formed by the top side 104, bottom side 105, and interior walls 124 of body 102 which span from top side 104 to bottom side 105. Body 102 is formed of a rigid plastic, but other materials such as plastic composites or metal are used in other versions. Assembly posts 130 joined to bottom side 105 provide screw holes to receive assembly screws for assembling tops side 104 to bottom side.

Air outlet 121 is formed in body 102 along the top wall of hollow chamber 120 and is adapted to align with a cooling air intake of the designated notebook computer when the external cooling module 100 is positioned in a designated relationship to the notebook computer, in this case with the notebook computer resting atop it. Structural support members 122 surround air outlet 121. In this embodiment, air outlet 121 has substantially the same planar area as the cooling air intake of the designated notebook computer and is positioned to cover the cooling air intake of the designated notebook computer when external cooling module 100 is positioned in the designated relationship to the designated computing device. Other versions use other sizing relationships for air outlet 121 relative to the cooling air intake, as further described below.

Shown in FIG. 2 is an external air intake 128 formed in body 102 and connected to a first portal 125 (FIG. 3) of hollow chamber 120. A blower such as a fan is positioned to force air through external air intake 128 into hollow chamber 120. In this version, the blower is positioned inside external air intake 128. An external power supply connection 114 supplies electrical power to the blower, controlled by a power switch 112. When activated by power switch 112, the blower maintains a positive air pressure in the hollow chamber 120 such that the positive air pressure is maintained against at least part of the cooling air intake of the designated notebook computer when air outlet 121 is aligned with the cooling air intake. In this embodiment, air outlet 121 is substantially the same area the cooling air intake of the designated notebook computer.

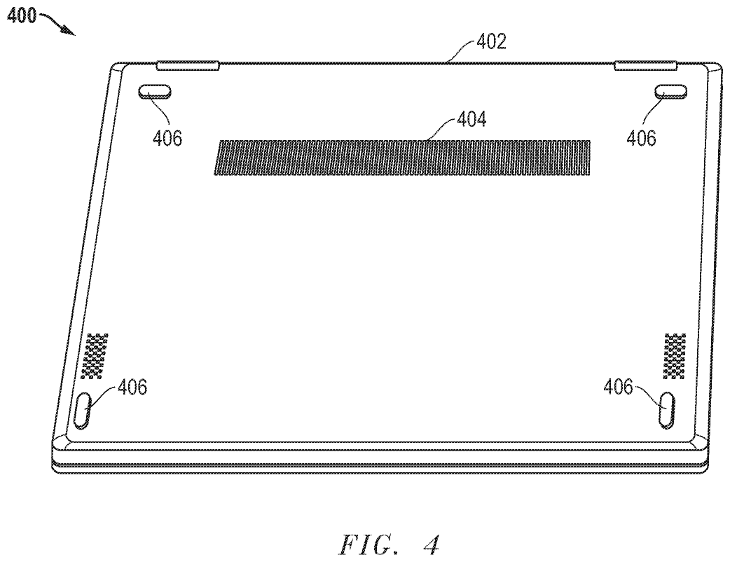

FIG. 4 is a bottom perspective view of a notebook computer 400 with which external cooling module 100 (FIG. 1) is designated to operate. In various embodiments, external cooling modules using the techniques herein are paired with various designated computing devices, with an air outlet positioned to align with the cooling air intake of the designated computing device. While a notebook computer 400 is shown as an example, other computer types such as desktop computers, blade server computers, and tablet computers are paired with external cooling modules in various embodiments. Notebook computer 400 includes a body 402, a cooling air intake 404, and supporting feet 406. A warm air outlet is present on the side of notebook computer 400.

Body 402 of computer 400 has cooling air intake 404 positioned along the lower face. Air outlet 121 (FIG. 1, FIG. 3) is positioned to align with cooling air intake 404 when notebook computer 400 is placed atop external cooling module 100. Notebook computer 400 has feet 406 which rest in indentations 108 (FIG. 1), allowing the body 402 to sit closer to or flush with top side 104 of external cooling module 100. By using an external cooling module that forces air through the cooling air intake of the computer with positive pressure, the CPU in notebook computer 400 operates cooler for a given workload, or alternatively, has higher performance capabilities at a given ambient temperature than a system with no external cooling module.

FIG. 5 illustrates in mixed cross-section and block diagram form an external cooling module 500 paired with a computer 50 according to some embodiments. The various depicted parts are not to scale. External cooling module 500 includes a body 502, a power switch 512, a control circuit 515, a hollow chamber 520, an air outlet 521, an external air intake 528, and a blower 530.

Hollow chamber 520 is formed in the interior of body 102. Air outlet 521 is formed along the top wall of hollow chamber 520 and is adapted to align with a cooling air intake of computer 50 when external cooling module 100 is positioned in a designated relationship to computer 50. In this embodiment, air outlet 521 has substantially the same planar area as the cooling air intake of a computer 50 and is positioned to cover the cooling air intake of computer 50 when external cooling module 100 is positioned in the designated relationship to computer 50. Hollow chamber 520 may include internal supporting structures, but generally provides an enclosed space allowing pressure to be maintained against the walls and at air outlet 521.

In this embodiment, blower 530 is a squirrel cage fan similar to those commonly employed to cool computers. In some versions, other fan types are used, such as axial mounted fans. As used herein, a blower includes fans and other blowing elements such as air multipliers. In operation, blower 530 forces air from external air intake 528 into hollow chamber 520 to maintain a positive air pressure in hollow chamber 520 such that the positive air pressure is maintained against the cooling air intake of computer 50 when air outlet 521 is aligned with the cooling air intake of computer 50.

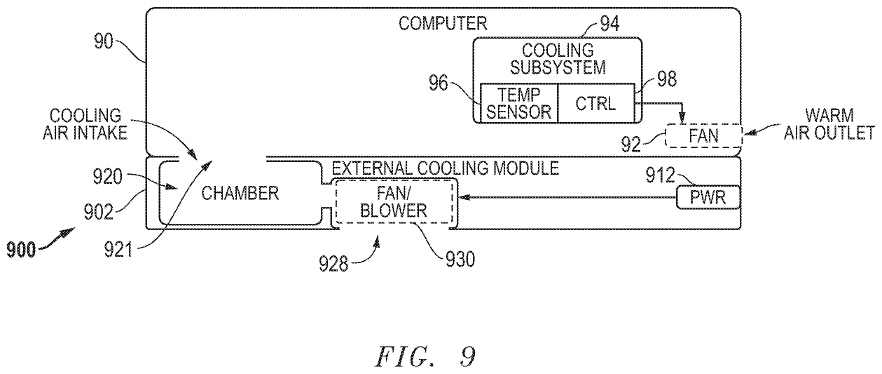

Computer 50 itself includes a fan 52 positioned to move air through a cooling air intake, and a cooling subsystem 54 including at least one temperature sensor 56 and a controller 58. Various internal cooling components of computer 50 are not shown but are often present, depending on the particular computer being paired with external cooling module 500. Such components include one or more air ducts to direct cooling air across desired components, thermal blocks coupled to the computer central processing unit (CPU) and graphics processing unit (GPU), heat pipes which conduct heat away from the thermal blocks, and heat spreaders thermally coupled to the heat pipes or directly to a thermal block. Some computers use internal air ducts, and some let air flow through the computer body without ducting. One or more temperature sensors 56 is typically thermally coupled to the CPU or GPU. Controller 58 receives readings from temperature sensor(s) 56 and controls the speed of one or more internal fans such as fan 52, positioned at a cooling air intake. A fan may be provided at an air outlet (such as the configuration of FIG. 9 below). Controller 58 is typically an embedded controller responsible for thermal management, and can perform other functions such as interfacing with other hardware in computer 50.

In some embodiments, external cooling module 500 is embodied in a notebook computer dock including power, network, and input/output connectors which connect to computer 50 when docked. Some versions of module 500 as a notebook computer dock include a control circuit 514 adapted to receive a signal from the computing device indicating a temperature state of the computing device, and based on the signal, adjust the blower 530. Driver software may be employed on computer 50 to obtain desired temperature state information and provide it to control circuit 514 over the depicted connecting serial link such as a universal serial bus (USB) connection or a wireless link.

While the number and position of cooling fans in particular computers vary, generally the cooling systems are designed with a designated or rated airflow required from the fan. However, for many reasons such as fan noise, price, and the specific arrangement of the airflow path, often the fans do not achieve their rated airflow. Further, the airflow designated for a particular cooling system is often not enough to carry away heat at the maximum applicable thermal carrying capacity of the thermal blocks, heat pipes, heat spreaders, or other heat sink arrangements employed in the cooling system.

In operation, blower 530 maintains a positive air pressure in hollow chamber 520 such that the positive air pressure is maintained against cooling air intake of computer 50 when aligned with the cooling air intake as depicted. As such, the air flow rate is increased to better cool computer 50, and employ more cooling capacity of cooling components therein. The positive pressure supplements fan 52 to drive more air through the cooling airflow path(s) of computer 50. Preferably, the positive air pressure maintained against the cooling air intake is sufficient to at least double an airflow rate for which a cooling system of computer 50 is rated. Such an arrangement is beneficial for use with all the embodiments described herein. For example, if the cooling subsystem is rated at 5 cubic feet per minute (CFM), an embodiment with this feature provides a blower 530 rated for at least 10 CFM. While at least doubling the airflow is described, the present inventor has found that a blower rated at 2-3 times the airflow provided by the computer's fan(s) (fan 52 in this example) is typically able to utilize much of the cooling capacity of the computer's cooling system elements.

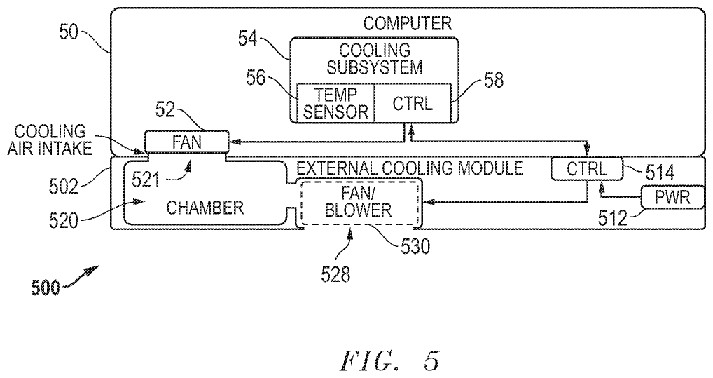

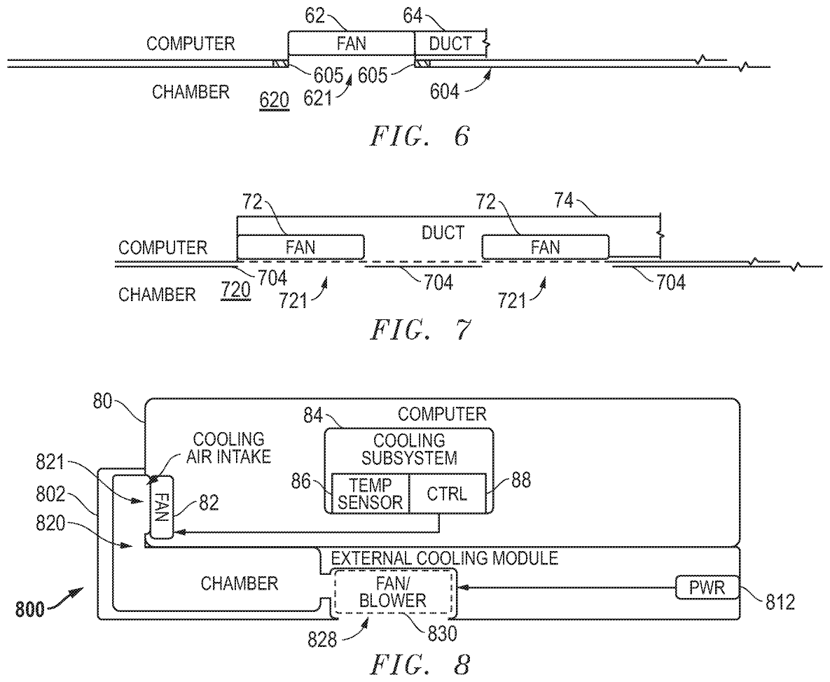

FIG. 6 is a cross-section block diagram showing a portion of a hollow chamber 620 aligned with a computer cooling air intake according to some embodiments. The top of hollow chamber 620 is depicted formed by the top side 604 of an external module. Air outlet 621 is formed in the top wall of hollow chamber 620 and is depicted aligned with a cooling air intake of a computer, at which is positioned an intake fan 62 forcing air into a duct 64. While a duct is shown in this version, other computers do not use ducting. A seal 605 is positioned along a perimeter of the air outlet 621 and configured to seal a connection between hollow chamber 620 and the cooling air intake of the computer when the external module is positioned in a designated relationship to the computer as depicted. Seal 605 is preferably made of a soft material such as foam or rubber. The use of a seal helps to maintain the positive air pressure against the cooling air intake.

FIG. 7 is a cross-section block diagram showing a portion of another hollow chamber 720 aligned with a computer cooling air intake according to additional embodiments. In this embodiment, the computer for which the external cooling module is designed to pair has an elongated cooling air intake with two intake fans 72 positioned along its length to force air into a duct 74. Hollow chamber 720 is has two air outlets formed in the top side 704 of external module, each positioned to maintain positive air pressure against only a portion of the cooling air intake of the computer. In this embodiment, air outlets 721 align with intake fans 72.

FIG. 8 is a cross section block diagram of an external cooling module 800 paired with a computer 80 according to some embodiments. In this version, an external cooling module 800 is designed to pair with a computer 80 having a cooling air intake located along a side wall rather than along the bottom side. External cooling module 800 includes a body 802, a power switch 812, a hollow chamber 820, an air outlet 821, a cooling air intake 828, and a blower 830. External cooling module 800 in some embodiments also includes a control circuit like control circuit 514 (FIG. 5) for receiving temperature state information from computer 80 and controlling blower 830 based on the temperature state information.

Computer 80 includes a fan 82 positioned to move air through a cooling air intake, and a cooling subsystem 84 including at least one temperature sensor 86 and a controller 88. Various other internal cooling components of computer 80, discussed above, are present in various implementations of computer 80.

Referring to external cooling module 800, body 802 includes a vertical extension formed along the left depicted side, vertically extending past the level of the computer 80 cooling air intake. Hollow chamber 820 is formed in the interior of body 802. Hollow chamber 820 extends into the vertical extension to the level of computer 80's cooling air intake.

Air outlet 821 is formed along the side wall of hollow chamber 820 in the vertically extending portion. Air outlet 821 is adapted to align with a cooling air intake of computer 80 when external cooling module 800 is positioned as depicted in a designated relationship to computer 80. In this embodiment, air outlet 821 has substantially the same planar area as the cooling air intake of a computer 80 and is positioned to cover the cooling air intake of computer 80 when external cooling module 800 is positioned as depicted. In some embodiments, air outlet 821 has a planar area smaller than that the cooling air intake, or a slightly larger planar area such as 5% or 10% larger. In operation, blower 830 maintains a positive air pressure in hollow chamber 820 such that the positive air pressure is maintained against cooling air intake of computer 80 when aligned with the cooling air intake as depicted. As such, external cooling module provides the improved airflow benefits discussed above, supplementing fan 82 of computer 80 to improve airflow through computer 80.

FIG. 9 is a cross section block diagram of another external cooling module 900 paired with a computer 90 according to some embodiments. In this version, an external cooling module 900 is designed to pair with a computer 90 having a fan 92 positioned at a warm air outlet of computer 90.

External cooling module 900 includes a body 902, a power switch 912, a hollow chamber 920, an air outlet 921, a cooling air intake 929, and a blower 930. External cooling module 900 in some embodiments also includes a control circuit like control circuit 514 (FIG. 5) for receiving temperature state information from computer 90 and controlling blower 930 based on the temperature state information.

Air outlet 921 is formed along the top wall of hollow chamber 920, and is adapted to align with a cooling air intake of computer 90 when external cooling module 900 is positioned as depicted in a designated relationship to computer 90. In this embodiment, air outlet 921 has substantially the same planar area as the cooling air intake of a computer 90 and is positioned to cover the cooling air intake of computer 90 when external cooling module 900 is positioned as depicted. In operation, blower 928 maintains a positive air pressure in hollow chamber 920 such that the positive air pressure is maintained against cooling air intake of computer 90 when aligned with the cooling air intake as depicted. As such, external cooling module provides the improved airflow benefits discussed above, supplementing fan 92 of computer 90 to improve airflow through computer 90.

Computer 90 includes a fan 92 positioned to move air out a warm air outlet. In some versions, the air is directed over a heat spreader (not shown separately) before exiting the warm air outlet. Computer 90 also includes a cooling subsystem 94 including at least one temperature sensor 96 and a controller 98. Various other internal cooling components of computer 90, discussed above, are present in various implementations of computer 90. In this version, no air ducting is used, and the cooling air flows inside the body of computer 90. In other versions, computer 90 may include internal air ducting to direct airflow from the cooling air intake, over heat sinks or heat spreaders in cooling subsystem 94, and out the warm air outlet. Some versions also include one or more fans at cooling air intakes forcing air into the body of computer 90.

While particular embodiments have been described, various modifications to these embodiments will be apparent to those skilled in the art. For example, while the computers discussed herein have cooling fans, other computers which have fanless cooling systems may also be paired with external cooling modules using the techniques herein. Furthermore, the air outlet of the external cooling module may be adjustable in size or position to better match the location of a cooling air intake of a computer, thereby adjusting the external cooling module to work with a different designated computing device. For example, one or more sliding panels may be employed on all or part of the hollow chamber edge allowing the size and/or position of the air outlet to be adjusted. Accordingly, it is intended by the appended claims to cover all modifications of the disclosed embodiments that fall within the scope of the disclosed embodiments.

What is claimed is:

1. An external module for use with a designated computing device, comprising:
a body forming a hollow chamber;
an external air intake formed in the body and connected to a first portal of the chamber;
an air outlet formed in the body along a wall of the chamber and adapted to align with a cooling air intake of the designated computing device when the external module is positioned in a designated relationship to the computing device; and
a blower positioned to force air through the external air intake into the chamber and maintain a positive air pressure in the chamber such that the positive air pressure is maintained against at least part of the cooling air intake of the computing device when the air outlet is aligned with the cooling air intake.

2. The external module of claim 1, wherein the air outlet has substantially the same planar area as the cooling air intake of a designated computing device and positioned to cover the cooling air intake of the designated computing device when the external module is positioned in the designated relationship to the designated computing device.

3. The external module of claim 1, wherein the air outlet is no larger than the cooling air intake of a designated computing device.

4. The external module of claim 3, wherein the air outlet is positioned to maintain positive air pressure against only a portion of the cooling air intake of the designated computing device, the portion aligned with an intake fan of the designated computing device.

5. The external module of claim 1, wherein the positive air pressure maintained against the cooling air intake is sufficient to at least double an airflow rate for which a cooling system of a designated computing device is rated.

6. The external module of claim 1, wherein the body comprises a notebook computer dock adapted to be electrically and physically coupled to the designated computing device.

7. The external module of claim 6, wherein the notebook computer dock includes a control circuit adapted to receive a signal from the computing device indicating a temperature state of the computing device, and based on the signal, adjust the blower.

8. The external module of claim 1, further comprising a seal positioned along a perimeter of the air outlet and configured to seal a connection between the chamber and the cooling air intake of the computing device when the external module is positioned in a designated relationship to the computing device.

9. A method comprising:
aligning an air outlet of a chamber of an external cooling device with a cooling air intake of a computing device;
driving air from an air intake to the chamber to pressurize the chamber with a positive air pressure; and
maintaining a positive air pressure against at least part of the cooling air intake of the computing device to increase airflow through a cooling system of the computing device.

10. The method of claim 9, wherein the air outlet is no larger than the cooling air intake of a designated computing device.

11. The method of claim 9, wherein the positive air pressure maintained against the cooling air intake is sufficient to at least double an airflow rate for which a cooling system of a designated computing device is rated.

12. The method of claim 9, further comprising receiving a signal from the computing device indicating a temperature state of the computing device, and based on the signal, adjusting a rate at which air is driven into the chamber.

13. The method of claim 9, further comprising sealing the air outlet to the cooling air intake of the computing device.

14. A system comprising:
a portable computing device including a cooling subsystem with a cooling air intake, a fan positioned to direct air toward selected components of the portable computing device, and an air outlet positioned to expel the air after it passes the selected components;
an external module adapted for pairing with the portable computing device, and including:
a body forming a chamber;
an external air intake formed in the body and connected to a first portal of the chamber;
an air outlet formed in the body along a wall of the chamber and adapted to align with a cooling air intake of the portable computing device when the external module is positioned in a designated relationship to the portable computing device; and
a blower positioned to force air through the external air intake into the chamber and maintain a positive air pressure in the chamber such that a positive air pressure is maintained against at least part of the cooling air intake of the portable computing device when the air outlet is aligned with cooling air intake.

15. The system of claim 14, wherein the air outlet is substantially the same planar area as the cooling air intake of the portable computing device and positioned to cover the cooling air intake of the portable computing device when the external module is positioned in the designated relationship to the portable computing device.

16. The system of claim 14, wherein the air outlet is no larger than the cooling air intake of the portable computing device.

17. The system of claim 16, wherein the air outlet is positioned to maintain positive air pressure against only portion of the cooling air intake of the portable computing device, the portion aligned with an intake fan of the portable computing device.

18. The system of claim 14, wherein the positive air pressure maintained against the cooling air intake is sufficient to at least double an airflow rate for which the cooling subsystem of the portable computing device is rated.

19. The system of claim 18, wherein the external module includes a control circuit adapted to receive a signal from the portable computing device indicating a temperature state of the portable computing device, and based on the signal, adjust the blower's speed.

20. The system of claim 14, wherein the fan is positioned to force air out of the air outlet of the portable computing device.
